(19) United States
(12) Patent Application Publication
(10) Pub. No.: US 2009/0284929 A1
(43) Pub. Date: Nov. 19, 2009

(54) HEAT DISSIPATION ASSEMBLY

(75) Inventor: RUNG-AN CHEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/169,644

(22) Filed: Jul. 9, 2008

(30) Foreign Application Priority Data
May 16, 2008 (CN) 200810067264.3

(51) Int. Cl. H05K 7/20

(52) U.S. Cl. 361/710

(57) ABSTRACT

A heat dissipation assembly (10) includes a heat sink (20) and a cover (30). The heat sink includes a base (22) and a plurality of fins (24) formed on a bottom surface of the base. A depression (220) is formed in a top surface of the base and has thermal interface material (40) received therein. The cover is removably secured to the top surface of the base of the heat sink and covers the depression.

### BACKGROUND

1. Technical Field

The present invention generally relates to a heat dissipation assembly having a heat sink, and more particularly to a heat dissipation assembly protecting thermal grease from contamination during transportation.

2. Description of Related Art

As computer technology continues to advance, electronic components such as central processing units (CPUs) of computers provide faster operational speeds and increased functional capabilities. When a CPU operates at high speed in a computer enclosure, its temperature increases greatly. It is necessary to dissipate the generated heat quickly, for example by using a heat sink attached to the CPU in the enclosure. This allows the CPU and other electronic components in the enclosure to function within their normal operating temperature ranges, thereby assuring the quality of data management, storage and transfer.

To improve heat conductivity between a heat sink and a CPU, thermal interface material such as thermal grease is often applied to a bottom face of the heat sink. However, thermal grease may contaminate surrounding articles or be contaminated by dust or foreign particles before attachment to the CPU.

What is needed, therefore, is a heat sink providing protection for thermal grease from contamination.

### SUMMARY

An exemplary embodiment of the present invention provides a heat dissipation assembly. The heat dissipation assembly includes a heat sink and a cover. The heat sink includes a base and a plurality of fins formed on a bottom surface thereof. A depression is formed in a top surface of the base and has thermal interface material received therein. The cover is removably secured to the top surface of the base of the heat sink and covers the depression.

Other advantages and novel features of the present invention will become more apparent from the following detailed description of embodiments when taken in conjunction with the accompanying drawings.

### BRIEF DESCRIPTION OF THE DRAWINGS

FIG. 1 is an exploded view of a heat dissipation assembly in accordance with an embodiment of the present invention.

FIG. 2 is an assembled, isometric view of the heat dissipation assembly of FIG. 1.

FIG. 3 is an assembled, isometric view of the heat dissipation assembly in accordance with another embodiment of the present invention.

### DETAILED DESCRIPTION

Reference will now be made to the drawing figures to describe the embodiments in detail.

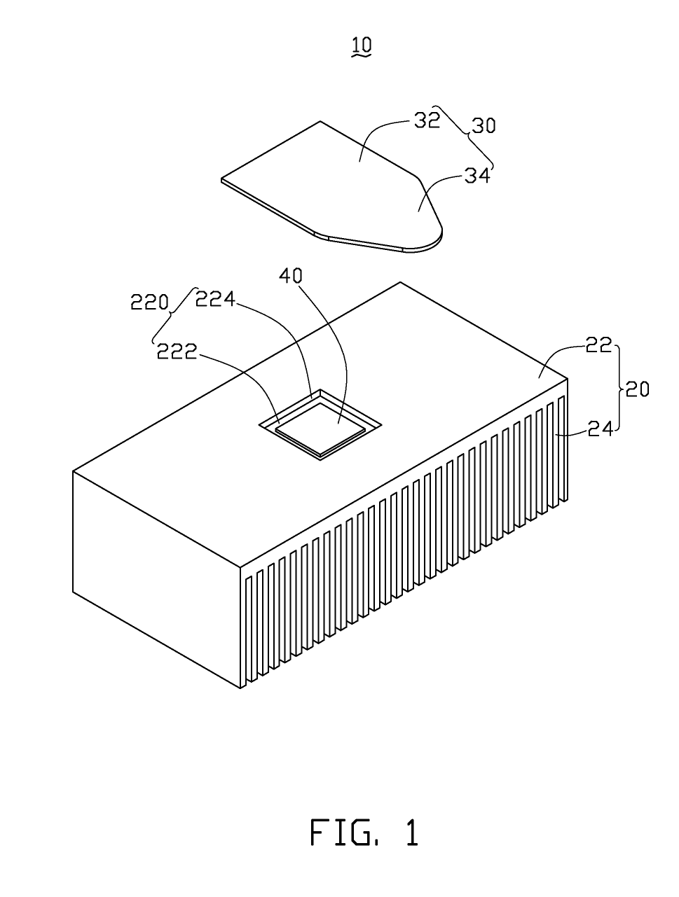

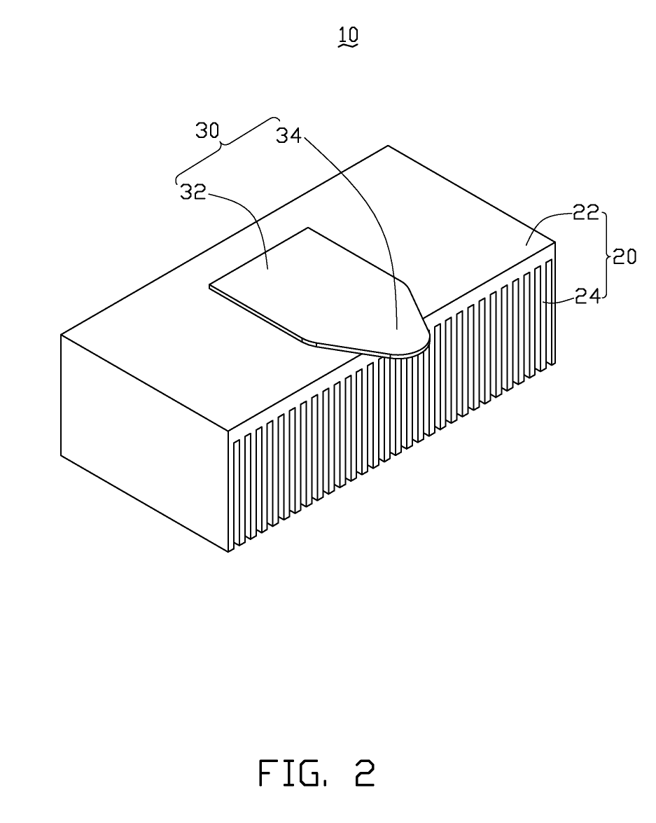

Referring to FIGS. 1-2, a heat dissipation assembly 10 in accordance with an embodiment of the present invention is illustrated. The heat dissipation assembly 10 includes a heat sink 20, thermal interface material 40 and a cover 30. The thermal interface material 40 can be thermal grease which is applied in the heat sink 20. The cover 30 is deployed on the heat sink 20.

The heat sink 20 includes a rectangular base 22 and a plurality of fins 24 formed on a bottom surface thereof. A rectangular depression 220 is formed in a top surface of the base 22. The depression 220 is defined by a bottom wall 222 and four sidewalls 224 extending from a periphery of the bottom wall 222.

The thermal interface material 40 is uniformly spread on a middle portion of the bottom wall 222. The thickness of the thermal interface material 40 is less than a depth of the depression 220. In other words, a top surface of the thermal interface material 40 is below the top surface of the base 22. In another embodiment, the thermal interface material 40 may be uniformly spread on the bottom wall 222 and the sidewalls 224 so that a large heat exchanging surface is obtained between the heat sink 20 and a heat source (not shown), such as a CPU. The heat source can be positioned to protrude into the depression 220.

The cover 30 is removably attached to the top surface of the base 22. The cover 30 is a flat sheet and may be divided into a rectangular main body 32 and a triangular tab 34. The main body 32 is larger than that of the depression 220 so as to cover the depression 220. The tab 34 is integrally formed with the main body 32 and extends beyond an edge of the top surface of the base 22. The width of the tab 34 is gradually reduced from the main body 32 towards a free end of the tab 34.

The cover 30 may be of plastic sheeting, and may be attached to the base 22 via a layer of glue spread on the base 22 in the vicinity of a periphery of the depression 220. In another embodiment, the cover 30 may be an adhesive tape, which can be directly attached to the top surface of the base 22 to cover the thermal interface material 40 in the depression 220 of the heat sink 20.

When the cover 30 is attached to the top surface of the base 22, the thermal interface material 40 is enclosed by the cover 30 and the depression 220. Thus, the thermal interface material 40 is protected from contamination before the heat sink 20 is attached to the heat source.

Prior to assembling the heat sink 20 to the heat source, the tab 34 can be easily employed to peel the cover 30 away from the heat sink 20 to expose the thermal interface material 40. The heat sink 20 and the heat source are then assembled together by a known procedure. By the provision of the cover 30, the thermal interface material 40 can be applied in the heat sink 20 in advance, thereby simplifying assembly of the heat sink 20 and the heat source. Since the cover 30 is flat, the possibility of dislodgement from the heat sink 20 by other components in a direction parallel to the cover 30, is greatly reduced.

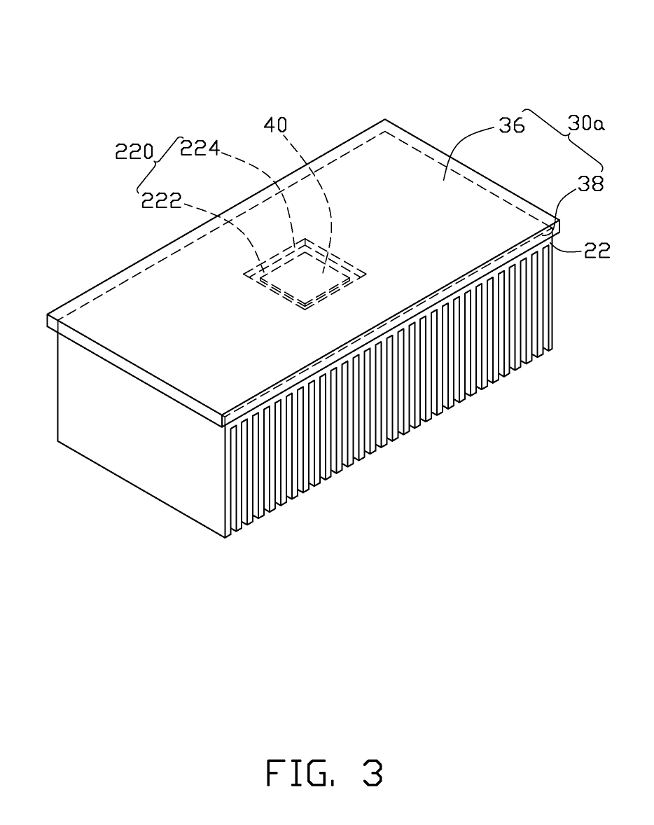

FIG. 3 shows a heat dissipation assembly in accordance with another embodiment of the present invention, differing from heat dissipation assembly 10 only in the structure of the cover 30a. The cover 30a includes a rectangular main body 36 and a lateral wall 38. The main body 36 is flat and is the same size as the base 22. The lateral wall 38 extends downwardly and perpendicularly from a peripheral edge of the main body 36.

When the cover 30a is mounted on the base 22, the main body 36 entirely contacts the top surface of the base 22 except for a portion above the depression 220. The lateral wall 38 is in close contact with four sides of the base 22 so that the cover 30a is mounted on the base 22.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A heat dissipation assembly comprising:
a heat sink comprising a base and a plurality of fins formed on a bottom surface thereof; and a flat cover comprising a main body and a tab, wherein
a depression is formed in a top surface of the base and has thermal interface material received therein, with the cover removably secured to the top surface of the base of the heat sink and covering the depression; and
wherein the main body of the flat cover is larger than the depression but smaller than the base of the heat sink and comprises a central portion and an outer periphery portion around the central portion, the outer periphery portion of the main body being attached to the top surface of the base around the depression, the central portion of the main body being located corresponding to and above the depression, the tab extending outwardly from the outer periphery portion of the main body to a place outside an edge of the top surface of the base.

2. The heat dissipation assembly of claim 1, wherein the depression is defined by a bottom wall and four sidewalls extending from a periphery of the bottom wall.

3. The heat dissipation assembly of claim 2, wherein the thermal interface material is spread on the bottom wall.

4. (canceled)

5. The heat dissipation assembly of claim 1, wherein the cover is an adhesive tape.

6. (canceled)

7. The heat dissipation assembly of claim 1, wherein the tab is integrally formed with the main body.

8. The heat dissipation assembly of claim 1, wherein the width of the tab is gradually reduced from the main body towards a free end of the tab.

9-10. (canceled)

11. The heat dissipation assembly of claim 1, wherein a top surface of the thermal interface material is below the top surface of the base of the heat sink.

12. A heat dissipation assembly comprising:
a heat sink comprising a surface to contact a heat source;
and a cover comprising a flat body and a tab, wherein
a depression in the surface of the heat sink has thermal interface material received therein, the flat body of the cover being larger than the depression but smaller than the surface of the heat sink and the cover is removably secured to the surface of the heat sink with the flat body covering the depression; and
wherein the flat body of the cover comprises a central portion and an outer periphery portion around the central portion, the outer periphery portion of the flat body being attached to the surface of the heat sink around the depression, the central portion of the flat body being located corresponding to and above the depression, the tab extending outwardly from the outer periphery portion of the flat body to a place outside an edge of the surface of the heat sink.

13. The heat dissipation assembly of claim 12, wherein the cover is an adhesive tape.

14. The heat dissipation assembly of claim 12, wherein the cover is fastened to the surface of the heat sink.

15. A heat dissipation assembly comprising:
a heat sink comprising a base having a face defining a depression therein, the depression being adapted for receiving an electronic heat source therein so that heat generated by the electronic heat source can be dissipated by the heat sink;
thermal interface material received in the depression; and
a cover covering the depression to protect the thermal interface material from contamination before removal of the cover from the heat sink; wherein
the cover has a main body larger than the depression but smaller than the base of the heat sink, and a tab extending from the main body to a place outside an edge of the base, the main body of the cover comprising a central portion and an outer periphery portion around the central portion, the outer periphery portion of the main body being attached to the face of the base around the depression, the central portion of the main body being located corresponding to and above the depression, the tab extending outwardly from the outer periphery portion of the main body.

16. (canceled)

17. The heat dissipation assembly of claim 15, wherein the tab has a triangular configuration.

18. (canceled)
